(19) United States
(12) Patent Application Publication
(10) Pub. No.: US 2025/0306106 A1
(43) Pub. Date: Oct. 2, 2025

(54) CONTACTOR WELD DETECTION

(71) Applicant: Cox Automotive, Inc., Atlanta, GA (US)

(72) Inventor: Connor Benjamin Taylor, Norman, OK (US)

(21) Appl. No.: 18/621,482

(22) Filed: Mar. 29, 2024

(51) Int. Cl. G01R 31/364; G01R 31/28; G01R 31/385; G01R 31/392

(52) U.S. Cl. CPC G01R 31/364; G01R 31/2841; G01R 31/385; G01R 31/392

(57) ABSTRACT

A system and method for determining a status of a plurality of contactors is provided. A plurality of exciters connected to a plurality of first nodes of a test circuit are triggered. Each of the plurality of exciters, when triggered, inject an excitation signal at an associated first node in the test circuit. A plurality of detectors connected to a plurality of second nodes of the test circuit are triggered. Each of the plurality of detectors, when triggered, detect a peak value of a resonant signal detected at an associated second node in the test circuit, and provide a digital output by comparing the peak value with a predetermined value. A status of a subset of a plurality of contactors of the test circuit is determined based on the digital output received from each of the plurality of detectors.

### BACKGROUND

Environmental impact of non-renewable energy sources such as coal, petroleum, natural gas, and the like has led to an increased popularity of electric vehicles and hybrid-electric vehicles among the general population. Electric and hybrid-electric vehicles employ electrochemical devices, for example, a rechargeable battery to power itself. These rechargeable batteries are subject to degradation based on usage and elemental exposure. Therefore, these rechargeable batteries are tested to determine a level of degradation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a diagram of an operating environment for contactor weld detection.

FIG. 2 is a diagram illustrating modules of a battery under test.

FIG. 3 is a diagram illustrating sections of a battery under test.

FIG. 4 is a block diagram illustrating an exciter.

FIG. 5 is a block diagram illustrating a detector.

FIG. 6 is a flow diagram of a method of contact weld detection.

FIG. 7 is a block diagram of a computing device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

During testing of electrochemical devices, multiple contacts are closed and opened. For example, a rechargeable battery is connected to a single power cycler using a first set of contacts and to an opposition battery using a second set of contracts to perform a test. The same rechargeable battery then is re-connected to another cycler or set of cyclers using another set of contacts to conduct another test. During these reconfigurations, it is important to make sure that the contactors are not welded. Welded contactors, for example, can cause short circuits and fire at the test facilities. Embodiments of the disclosure provide a system and method for contactor weld detection. Embodiments of the present disclosure provide techniques for determining a status of one or more contactors (that is, whether one or more contactors are welded or not).

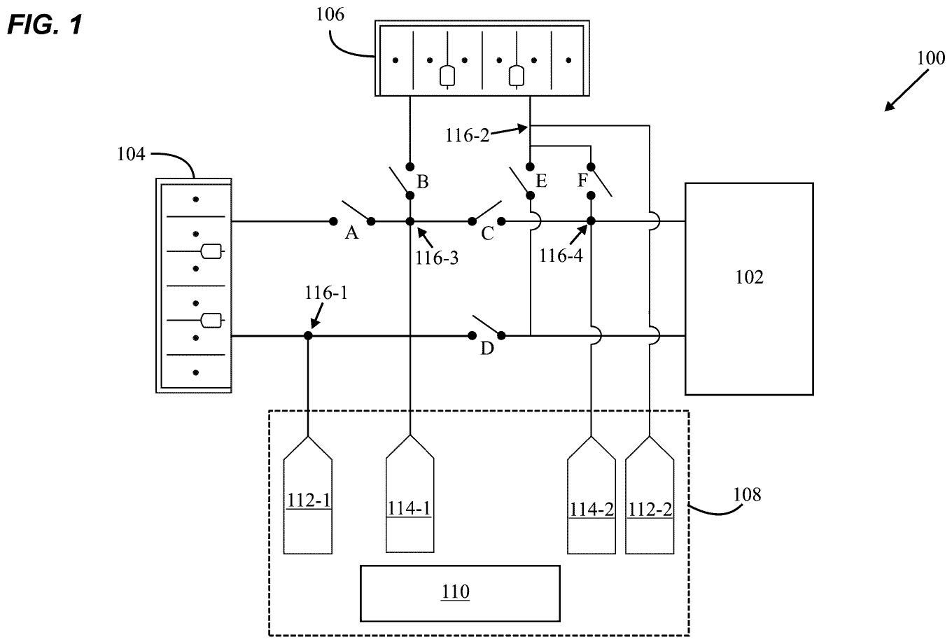

FIG. 1 is a diagram illustrating an operating environment 100 for a contact weld detection. In some examples, operating environment 100 is a testing environment or a test circuit for electrochemical devices, for example, a rechargeable battery. As shown in FIG. 1, operating environment 100 includes a power cycler 102, a battery under test 104, an opposition battery 106, and a contactor weld detection system 108. Power cycler 102, battery under test 104, and opposition battery 106 are connected to each other through a plurality of contactors or switches, for example, A, B, C, D, and E. Contactor weld detection system 108 includes a controller 110, a plurality of exciters (for example, a first exciter 112-1 and a second exciter 112-2) and a plurality of detectors (for example, a first detector 114-1 and a second detector 114-2). Although contactor weld detection system 108 of operating environment 100 is shown to include only two exciters and only two detectors, it may include a different number of exciters and detectors. In addition, operating environment 100 may include a more than one battery under test and more than one opposition battery.

Battery under test 104 can be connected to power cycler 102 by closing contactors A, C, and D. Opposition battery 106 can be connected to power cycler 102 and battery under test 104 by closing contactors A, B, C, D, and E. When connected, a negative terminal of power cycler 102 is connected to a negative terminal of battery under test 104, a positive terminal of battery under test 104 is connected to a negative terminal of opposition battery 106, and a positive terminal of opposition battery 106 is connected to positive terminal of power cycler 102. Thus, opposition battery 104 is connected to in opposition to battery under test 104 from power cycler 102 point of view.

The plurality of exciters and the plurality of detectors of contactor weld detection system 108 are connected at different nodes in operating environment 100. In one example configuration, first exciter 112-1 is connected at a first node 116-1 located between the negative terminal of battery under test 102 and contactor D and second exciter 112-2 is connected at a second node 116-2 located between the positive terminal of opposition battery under test 106 and contactor E. In this example configuration, first detector 114-1 is connected at a third node 116-3 located between contactors A, B, and C and second detector 114-2 is connected at a fourth node 116-4 located between the positive terminal of power cycler 102 and contactor C. Contactor F may connect second detector 114-2 to second node 114-2.

Power cycler 102 is configured to inject/withdraw a predetermined amount of current to/from battery under test 104. Power cycler 102, thus, can charge or discharge battery under test 104 by injecting current into or withdrawing current from battery under test 104. Power cycler 102 is connected to a power grid through a grid connection (not shown) or to another power source. Power cycler 102 may source power for charging battery under test 104 from the power grid or another power source. In addition, power cycler 102 may also recycle any power harvested during discharging of battery under test 104 back to the power grid through the grid connection.

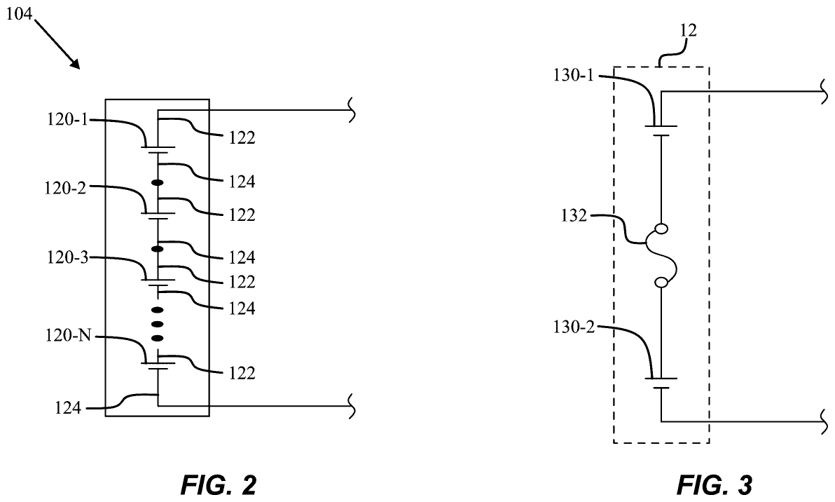

Battery under test 104 may be a rechargeable battery. In some embodiments, battery under test 104 is recovered from a vehicle, for example, an electric vehicle. Battery under test 104 may include a plurality of battery modules connected together. In examples, a module may be the smallest unit of battery under test 104 without breaking any permanent mechanical systems. FIG. 2 illustrates an example battery under test 104. As shown in FIG. 2, battery under test 104 may include a plurality of battery modules, 120-1, 120-2, 120-3, . . . , 120-N connected together. It may be understood that battery under test 104 may include any number of battery modules. For example, battery under test 104 may include any number of battery modules, including 28, 30, 38, 40, or 48 battery modules.

Each of the plurality of battery modules have a positive terminal 122 and a negative terminal 124. The plurality of battery modules can be combined in a series configuration in which positive terminal 122 of one of the plurality of battery modules is connected to negative terminal 124 of an adjacent battery module. In some arrangement, one or more battery modules are connected in parallel while some battery modules are connected in series. A total capacity and voltage rating of battery under test 104 may depend on a number of battery modules included in battery under test 104 and the connection configuration of the battery modules. Each of the plurality of battery modules may include one or more cells (not shown) connected together. A capacity and voltage rating of a battery module may depend on a number of battery cells included in the battery module and connection configuration of the battery cells.

In some examples, one or more fuses may divide battery under test 104 into two or more sections or groupings. Battery sections are generally composed of a plurality of modules and may be structured for case in disassembly and reconstituted through the use of removable hardware (e.g., threaded rods with removable nuts). These structures may arise for two reasons. First is the requirement for mechanical compression which may be required for proper functioning. Second, intermediate electrical equipment, such as fuses and contactors, are positioned for safety and operation. For example, fuses are typically located mid-battery pack so that removal of the fuse reduces battery voltage by half.

FIG. 3 is a diagram illustrating sections of battery under test 104. As shown in FIG. 3, battery under test 104 includes two sections, a first section 130-1 and a second section 130-2 connected by a fuse 132. Each of first section 130-1 and second section 130-2 may include multiple battery modules, for example, 28, 30, 38, 40, etc. A number of battery modules in each of first section 130-1 and second section 130-2 may be same or different depending on a design consideration of battery under test 104. In addition, battery under test 104 may include more than two modules and the modules do not have to be separated by fuse 132. Moreover, in some examples, if present, fuse 132 does not have to be between sections, and can be located anywhere along a current path. For example, fuse 132 can be located anywhere on exterior of battery under test 104 so that fuse 132 is more accessible by a user.

Referring back to FIG. 1, opposition battery 106 may be similar in configuration to battery under test 104. For example, opposition battery 106 may include a plurality of battery modules, battery section, or a combination of battery modules and battery sections connected together. The plurality of battery modules for opposition battery 106 may be assembled from different battery packs. A total capacity and voltage rating of opposition battery 106 may depend on the number of battery modules included in battery under test 104 and connection configuration of the battery modules.

A capacity of opposition battery 106 may be determined for each test and may depend on the capacity of power cycler 102 and that of the battery under test 104. For example, a capacity of opposition battery 106 may be n-times of a capacity of battery under test 104, where n is predefined range. In one example, if battery under test 104 is rated at 60 KWH then opposition battery 106 may be rated at 300 KWH (that is, 5 times) or higher.

In example embodiments, a voltage rating of opposition battery 106 is lower than the voltage rating of the battery under test 104. A difference in the voltage ratings of battery under test 104 and opposition battery 106 may depend on ratings of power cycler 102 and the capacity of the grid connection or other power source available at the test facility. In one example, a voltage output of power cycler 102 is higher than the difference between the voltage ratings of the battery under test 104 and opposition battery 106, but not much higher. The greater the difference between the voltage rating of power cycler 102 and the difference between battery under test 104 and opposition battery 106 voltage rating, the faster the charging process, but also the greater the risk of overcharging and damaging battery under test 104. In one example, if battery under test 104 is rated at 800V then opposition battery 106 may be rated at 700V. In this example, a voltage difference at terminals of power cycler 102 is 100V. In other examples, a voltage difference at terminals of power cycler 102 can be 50V, 150 V, 200V, etc.

The voltage difference at the terminals of power cycler 102 and the capacity of opposition battery 106, may be based on the capacity of the grid connection or other power source at the testing facility. For example, a lower voltage difference and, hence, a higher capacity and a higher voltage rated opposition battery 106 is used for a lower capacity grid connection. On the contrary, a higher voltage difference and, hence, a lower capacity and a lower voltage rated opposition battery 106 may be used for a higher capacity grid connection.

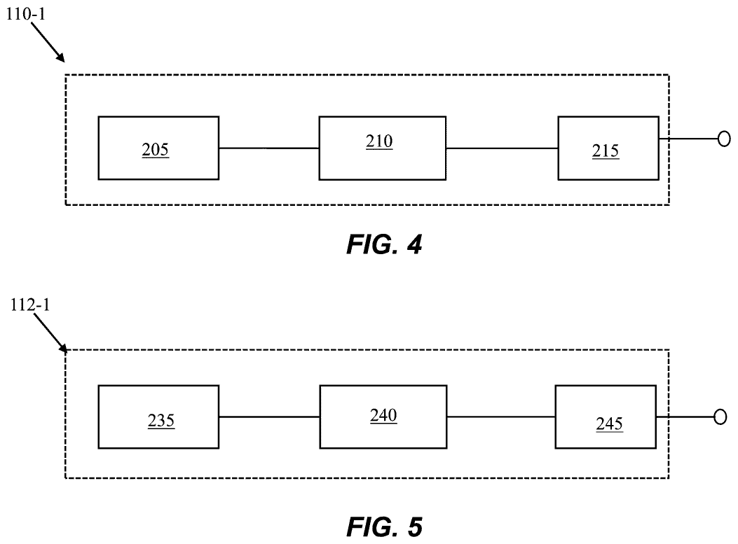

FIG. 4 is a block diagram illustrating first exciter 112-1 of contactor weld detection system 108. As shown in FIG. 4, first exciter 112-1 includes a signal generator 205, a low pass filter 210, and a first isolator 215. Signal generator 205 is connected to a first terminal of low pass filter 210. A second terminal of low pass filter 210 is connected to a first terminal of isolator 215. A second terminal of isolator 215 is connected to an associated node, for example, first node 116-1 of operating environment 100.

In one example, signal generator 205 generates a pulse signal with a predetermined frequency and amplitude. In one example, the pulse signal has a frequency of 20 MHz frequency and an amplitude of IV. The pulse signal is provided to low pass filter 210. Low pass filter 210 converts the pulse signal into an input signal, for example, a sine wave signal. The sine wave signal is provided to the input terminal of first isolator 215. First isolator 215 couples or propagates the sine wave signal to operating environment 100. First isolator 215 electrically decouples first exciter 112-1 from functioning of the test circuit of operating environment 100. In some examples, first isolator 215 is a capacitor, a resonant circuit, etc. When triggered, first exciter 112-1 injects the excitation signal to an associated node, for example, first node 116-1. Other exciters (that is, second exciter 112-2) is similar to first exciter 112-1 and is not being described in detail for brevity of the specification. When triggered, second exciter 112-2 injects the excitation signal to an associated node, for example, second node 116-2 of operating environment 100.

FIG. 5 is a block diagram illustrating first detector 114-1 of contactor weld detection system 108. As shown in FIG. 5, first detector 114-1 includes an analog to digital convertor 235, a peak detector 240, and a second isolator 245. Analog to digital convertor 235 is connected to a first terminal of peak detector 240. A second terminal of peak detector 240 is connected to a first terminal of second isolator 245. A second terminal of second isolator 245 is connected to an associated node, for example, third node 116-3 of operating environment 100. Second isolator 245 electrically decouples first detector 114-1 from functioning of the test circuit of operating environment 100. In some examples, second isolator 245 is a capacitor, a resonant circuit, etc.

Based on an impedance between the plurality of exciters and first detector 114-1, some of the sine wave signal injected into operating environment 100 is reflected back or resonate towards first detector 114-1. Peak detector 240 measures a peak value (that is, an amplitude) of resonant signal and provides the measured peak value to analog to digital convertor 235. Analog to digital convertor 235 converts the peak value into a digital value, for example, 0 or 1. For example, analog to digital convertor 235 compares the peak value to a predetermined value and provides the digital value based on the comparison. In one example, if the peak value is greater than the predetermined value, then analog to digital convertor 235 provides the digital output of 1. However, if the peak value is lesser than the predetermined value, then analog to digital convertor 235 provides the digital output of 1. When triggered, first detector 114-1 detects resonant signal at an associated node, for example, third node 116-1 and provides a digital output corresponding to the detected resonant signal. Other detectors (that is, second detector 114-2) is similar to first detector 114-1 and is not being described in detail for brevity of the specification. When triggered, second detector 114-2 detects resonant signal at an associated node, for example, fourth node 116-4 and provides a digital output corresponding to the detected resonant signal.

Referring back to FIG. 1 and as described in the following sections of the disclosure, contactor weld detection system 108 monitors and determines a status of contactors A, B, C, D, and E operating environment 100. That is, contactor weld detection system 108 determines whether one or more of contactors A, B, C, D, and E are welded. For example, controller 110 can trigger the plurality of exciters to inject excitation signal into operating environment 100. Controller 110 then receives the digital output from each of the plurality of detectors. Based on the digital output received from the plurality of detectors, controller 100 then determines whether and which one or more of contactors A, B, C, D, and E are welded shut.

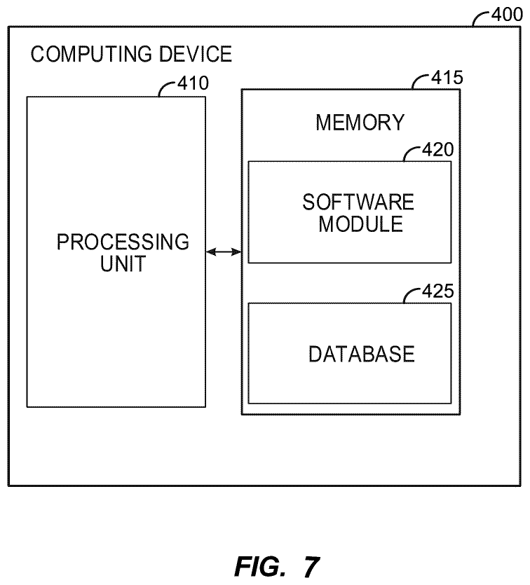

The elements described above of contactor weld detection system 108 (e.g., controller 110, first exciter 112-1, second exciter 112-2, first detector 114-1, and second detector 114-2) may be practiced in hardware and/or in software (including firmware, resident software, micro-code, etc.) or in any other circuits or systems. The elements of contactor weld detection system 108 may be practiced in electrical circuits comprising discrete electronic elements, packaged or integrated electronic chips containing logic gates, a circuit utilizing a microprocessor, or on a single chip containing electronic elements or microprocessors. Furthermore, the elements of contactor weld detection system 110 may also be practiced using other technologies capable of performing logical operations such as, for example, AND, OR, and NOT, including but not limited to, mechanical, optical, fluidic, and quantum technologies. As described in greater detail below with respect to FIG. 7, the elements of contactor weld detection system 108 may be practiced in a computing device 400.

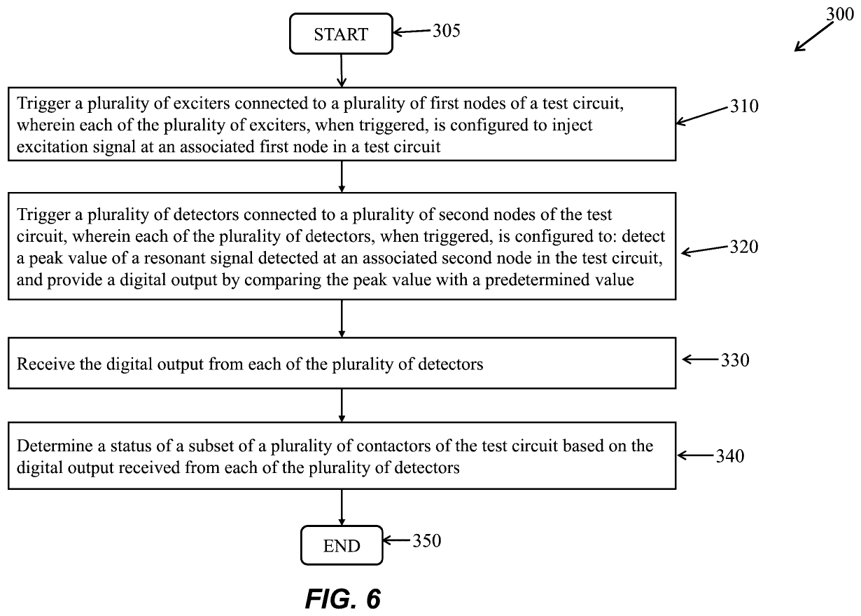

FIG. 6 is a flow chart setting forth the general stages involved in a method 300 consistent with an embodiment of the disclosure for contactor weld detection. Method 300 may be performed by contactor weld detection system 108 or controller 110 of contactor weld detection system 108. Ways to implement the stages of method 300 will be described in greater detail below.

Method 300 begins at starting block 305 and proceeds to stage 310 a plurality of exciters connected to a plurality of first nodes of a test circuit are triggered. When triggered, ach of the plurality of exciters is configured to inject an excitation signal at an associated first node in the test circuit. For example, controller 110 triggers each of first exciter 110-1 connected at first node 114-1 and second exciter 110-2 connected at second node 114-2. When triggered, first exciter 110-1 injects excitation signal at first node 114-1 and second exciter 110-2 injects excitation signal at second node 114-2 of operating environment 100. As discussed above, the excitation signal may be a high frequency sign wave signal that does not interfere with workings of operating environment. The excitation signal propagates through the test circuit of operating environment 100 depending on status of contactors A, B, C, D, E. The excitation signal may not propagate to portions of the test circuit that are isolated because of one or more of contactors A, B, C, D, and E are open. For example, if each of contactors A, B, and C are open, then the excitation signal may not be able to propagate to third node 116-3. However, if any of contactors A, B, and C are welded or close, the excitation signal may be able to propagate to third node 116-3 through the welded contact.

After triggering the plurality of exciters at stage 310, method 300 proceeds to stage 320 where a plurality of detectors connected to a plurality of second nodes of the test circuit are triggered. When triggered, each of the plurality of detectors is configured to: detect a peak value of a resonant signal detected at an associated second node in the test circuit and provide a digital output by comparing the peak value with a predetermined value. For example, controller 110 may trigger each of first detector 114-1 and second detector 114-2. When triggered, first detector 114-1 detects resonant signal at third node 116-1 and provides a digital output corresponding to the detected resonant signal. In addition, when triggered, second detector 114-2 detects resonant signal at fourth node 116-4 and provides a digital output corresponding to the detected resonant signal.

Once having triggered the plurality of detectors at stag 320, method 300 proceeds to stage 330 where the digital output is received from each of the plurality of detectors. For example, controller 110 receives the digital output from each of the first detector 114-1 and second detector 114-2.

After receiving the digital output from each of the plurality of detectors at stage 330, method 300 proceeds to stage 350 where a status of a subset of a plurality of contactors of the test circuit are determined based on the digital output received from each of the plurality of detectors. For example, controller 110 determines whether one or more of contactors A, B, C, D, and E are welded based on the digital output from first detector 114-1 and second detector 114-2. Controller 110 can determine that none of a status of one or more contactors A, B, C, D, and E welded if the digital output of both first detector 114-1 and second detector 114-2 is 0. In another example, if the digital output of first detector 114-1 is 1 and the digital output of second detector 114-2 is 0, then controller 110 may determine that one or both of contactors A and B are welded. In yet another example, if the digital output of first detector 114-1 is 0 and the digital output of second detector 114-2 is 1, then controller 110 may determine that one or more of contactors D, E, and F are welded.

In example embodiments, controller 110 may compare with the digital output of the plurality of detectors with a pre-determined values to determine which contactors are welded. Such table may be stored on a memory device. In some embodiments, controller 110 may provide an indication that one or more contacts are welded. Such indications may be provided through a visual indicator, for example, a blinking light or as an audible alarm. The locations or identifiers of welded contactors may be displayed as well. Once having determined the status of the subset of the plurality of contactors at stage 340, method 300 may terminate at END block 350.

FIG. 7 shows computing device 400. As shown in FIG. 7, computing device 400 includes a processing unit 410 and a memory unit 415. Memory unit 415 includes a software module 420 and a database 425. While executing on processing unit 410, software module 420 performs, for example, processes for a contactor weld detection, including for example, any one or more of the stages from method 300 described above with respect to FIG. 6. Computing device 400, for example, provides an operating environment for power cycler 102, contactor weld detection system 108, controller 110, first exciter 112-1, second exciter 112-2, signal generator 205, low pass filter 210, first isolator 215, analog to digital convertor 235, peak detector 240, and second isolator 245. Power cycler 102, contactor weld detection system 108, controller 110, first exciter 112-1, second exciter 112-2, signal generator 205, low pass filter 210, first isolator 215, analog to digital convertor 235, peak detector 240, and second isolator 245 may operate in other environments and are not limited to computing device 400.

Computing device 400 can be implemented using a tablet device, a mobile device, a smart phone, a telephone, a remote control device, a personal computer, a network computer, a mainframe, a router, a switch, a server cluster, a smart TV-like device, a network storage device, a network relay device, or other similar microcomputer-based device. Computing device 400 can include any computer operating environment, such as hand-held devices, multiprocessor systems, microprocessor-based or programmable sender electronic devices, minicomputers, mainframe computers, and the like. Computing device 400 can also be practiced in distributed computing environments where tasks are performed by remote processing devices. The aforementioned systems and devices are examples and computing device 400 can comprise other systems or devices.

Embodiments of the disclosure, for example, can be implemented as a computer process (method), a computing system, or as an article of manufacture, such as a computer program product or computer readable media. The computer program product can be a computer storage media readable by a computer system and encoding a computer program of instructions for executing a computer process. The computer program product can also be a propagated signal on a carrier readable by a computing system and encoding a computer program of instructions for executing a computer process. Accordingly, the present disclosure can be embodied in hardware and/or in software (including firmware, resident software, micro-code, etc.). In other words, embodiments of the present disclosure can take the form of a computer program product on a computer-usable or computer-readable storage medium having computer-usable or computer-readable program code embodied in the medium for use by or in connection with an instruction execution system. A computer-usable or computer-readable medium can be any medium that can contain, store, communicate, propagate, or transport the program for use by or in connection with the instruction execution system, apparatus, or device.

The computer-usable or computer-readable medium can be, for example but not limited to, an electronic, magnetic, optical, electromagnetic, infrared, or semiconductor system, apparatus, device, or propagation medium. More specific computer-readable medium examples (a non-exhaustive list), the computer-readable medium can include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

While certain embodiments of the disclosure have been described, other embodiments may exist. Furthermore, although embodiments of the present disclosure have been described as being associated with data stored in memory and other storage mediums, data can also be stored on or read from other types of computer-readable media, such as secondary storage devices, like hard disks, or a CD-ROM, a carrier wave from the Internet, or other forms of RAM or ROM. Further, the disclosed methods' stages may be modified in any manner, including by reordering stages and/or inserting or deleting stages, without departing from the disclosure.

Furthermore, embodiments of the disclosure may be practiced in an electrical circuit comprising discrete electronic elements, packaged or integrated electronic chips containing logic gates, a circuit utilizing a microprocessor, or on a single chip containing electronic elements or microprocessors. Embodiments of the disclosure may also be practiced using other technologies capable of performing logical operations such as, for example, AND, OR, and NOT, including but not limited to, mechanical, optical, fluidic, and quantum technologies. In addition, embodiments of the disclosure may be practiced within a general purpose computer or in any other circuits or systems.

Embodiments of the disclosure may be practiced via a system-on-a-chip (SOC) where each or many of the element illustrated in FIGS. 1-5 may be integrated onto a single integrated circuit. Such a SOC device may include one or more processing units, graphics units, communications units, system virtualization units and various application functionality all of which may be integrated (or “burned”) onto the chip substrate as a single integrated circuit. When operating via a SOC, the functionality described herein with respect to embodiments of the disclosure, may be performed via application-specific logic integrated with other components of computing device 400 on the single integrated circuit (chip).

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

What is claimed is:

1. A system for determining a status of a plurality of contactors of a test circuit, the system comprising:
a controller;
a plurality of exciters, wherein each of the plurality of exciters, when triggered, is configured to inject excitation signal at an associated first node in a test circuit;
a plurality of detectors, wherein each of the plurality of detectors, when triggered, is configured to:
detect a peak value of a resonant signal detected at an associated second node in the test circuit, and
provide a digital output by comparing the peak value with a predetermined value; and
wherein the controller is configured to:
trigger each of the plurality of exciters and each of the plurality of detectors,
receive the digital output from each of the plurality of detectors, and
determine that a status of a subset of a plurality of contactors of the test circuit based on the digital output received from the plurality of detectors.

2. The system of claim 1, wherein each of the plurality of exciters comprises a signal generator, a low pass filter connected to the signal generator, and an isolator connected to the low pass filter.

3. The system of claim 2, wherein the signal generator is configured to generate a pulse signal with a predetermined frequency.

4. The system of claim 3, wherein the low pass filter is configured to convert the pulse signal into a sine wave signal.

5. The system of claim 2, wherein the isolator comprises one of a capacitor, a resonance circuit, or a galvanic transformer.

6. The system of claim 1, wherein each of the plurality of detectors comprises an analog to digital convertor, a peak detector connected to the analog to digital convertor, and an isolator connected to the peak detector.

7. The system of claim 6, wherein the peak detector is configured to detect the peak value of the resonant signal detected at the associated second node in the test circuit.

8. The system of claim 6, wherein analog to digital convertor is configured to convert the peak value to the digital output by comparing the peak value with the predetermined value.

9. The system of claim 1, wherein the test circuit comprises a rechargeable battery connected to an opposition battery and a power cycler through the plurality of contactors.

10. A contactor weld detection system comprising a controller, wherein the controller is configured to:
trigger a plurality of exciters connected to a plurality of first nodes of a test circuit, wherein each of the plurality of exciters, when triggered, is configured to inject excitation signal at an associated first node of the test circuit;
trigger a plurality of detectors connected at a plurality of second nodes of the test circuit, wherein each of the plurality of detectors, when triggered, is configured to:
detect a peak value of a resonant signal detected at an associated second node in the test circuit, and
provide a digital output by comparing the peak value with a predetermined value;
receive the digital output from each of the plurality of detectors; and
determine a status of a subset of a plurality of contactors of the test circuit based on the digital output received from each of the plurality of detectors.

11. The contactor weld detection system of claim 10, wherein the associated first node is separated from the associated second node by at least one contactor of the plurality of contactors.

12. The contactor weld detection circuit of claim 10, wherein the test circuit comprises at least one rechargeable battery connected to an opposition battery and a power cycler through the plurality of contactors.

13. The contactor weld detection system of claim 12, wherein the opposition battery is connected in opposition to the at least one rechargeable battery from the power cycler view.

14. The contactor weld detection system of claim 12, wherein the power cycler is configured to inject a pulse current into the rechargeable battery and determine a status of the rechargeable battery based on a response of the rechargeable battery to the pulse current.

15. The contactor weld detection system of claim 10, wherein the plurality of contactors comprises at least two contactors.

16. The contactor weld detection system of claim 10, wherein the controller is further configured to provide an alarm in response to determining that one or more the plurality of contactors is welded.

17. A method of determining a status of a contact, the method comprising:
triggering a plurality of exciters connected to a plurality of first nodes of a test circuit, wherein each of the plurality of exciters, when triggered, is configured to inject an excitation signal at an associated first node in a test circuit;
triggering a plurality of detectors connected to a plurality of second nodes of the test circuit, wherein each of the plurality of detectors, when triggered, is configured to:
detect a peak value of a resonant signal detected at an associated second node in the test circuit, and
provide a digital output by comparing the peak value with a predetermined value;
receiving the digital output from each of the plurality of detectors; and
determining a status of a subset of a plurality of contactors of the test circuit based on the digital output received from each of the plurality of detectors.

18. The method of claim 17, wherein determining the status comprises:
determining whether any of the plurality of contacts is welded.

19. The method of claim 18, further comprising:
providing an alert in response to determining that one or more the plurality of contactors is welded.

20. The method of claim 17, wherein the excitation signal comprises a sine wave signal.
